(19) United States
(12) Patent Application Publication
(10) Pub. No.: US 2008/0297262 A1
(43) Pub. Date: Dec. 4, 2008

(54) Increased gain high-frequency amplifier

(76) Inventors: Jon S. Duster, Beaverton, OR (US); Stewart S. Taylor, Beaverton, OR (US)

Correspondence Address: RYDER IP LAW;C/O INTELLEVATE, LLC, P. O. BOX 52050, MINNEAPOLIS, MN, 55402, US

(21) Appl. No.: 11/809,071

(22) Filed: May 31, 2007

(51) Int. Cl. H03F 1/22

(52) U.S. Cl. 330/311

(57) ABSTRACT

In general, in one aspect, the disclosure describes an amplifier that includes a first transistor coupled to ground and a second transistor coupled to the first transistor and a supply voltage. A voltage biasing circuit is used to provide biased voltages to the first and second transistors. An inductor coupled between the voltage biasing circuit and the second transistor.

### BACKGROUND

Amplifiers are commonly utilized in circuit designs. Amplifiers may provide limited gain in certain technologies at a frequency band of interest. In order to enhance the gain the amplifier may utilize more current or may incorporate more stages. Such changes to the amplifier may result in additional power being consumed by the amplifier and/or the amplifier requiring additional die area. Additionally, modifying the amplifier may effect (increase) the noise figure of the amplifier.

### BRIEF DESCRIPTION OF THE DRAWINGS

The features and advantages of the various embodiments will become apparent from the following detailed description in which:

FIG. 1A illustrates a high level schematic diagram of an example tuned cascode amplifier, according to one embodiment; and

FIG. 1B illustrates a simplified detailed schematic diagram of an example tuned cascode amplifier, according to one embodiment.

### DETAILED DESCRIPTION

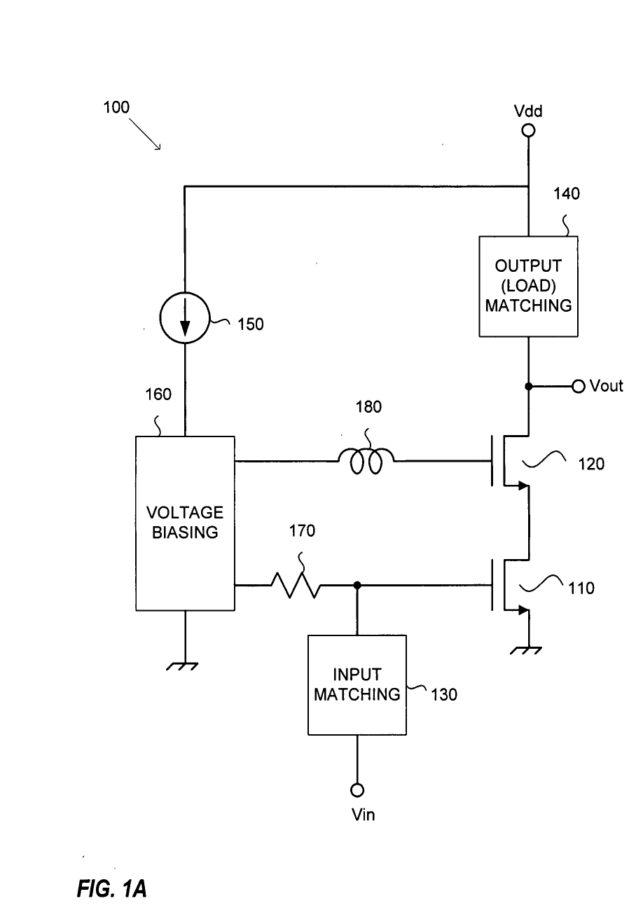

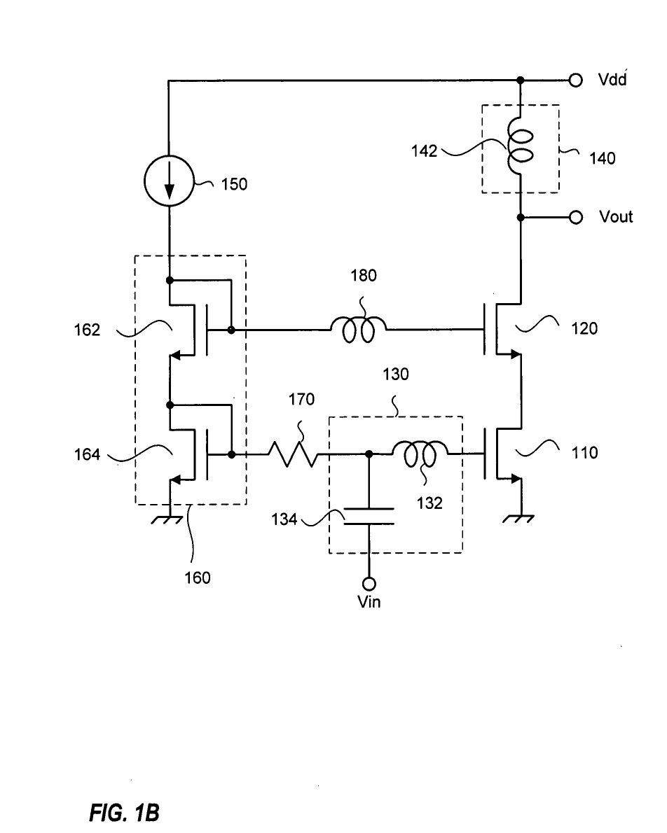

FIG. 1A illustrates a simplified schematic diagram of an example tuned cascode amplifier 100. The amplifier 100 includes a first transistor 110 (common source) and a second transistor 120 (common gate) connected in series (drain of 110 to source of 120) between ground and a supply voltage (Vdd). The first transistor 110 is illustrated as being directly connected to ground (source to ground) but is not limited thereto. Rather the first transistor 110 is electrically coupled to ground, and other components (not illustrated), such as inductors, may be connected between the first transistor 110 and ground.

The amplifier 100 also includes an input matching network 130, an output matching network 140, a current source 150, a voltage biasing circuit 160, a resistor 170, and an inductor 180. The input to the amplifier 100 is provided to the gate of the first transistor 110 via the input matching network 130. The drain of the second transistor 120 provides the output of the amplifier 100. At least a portion of the output matching network 140 is provided between the second transistor 120 and Vdd. The output matching network 140 may also include other elements not shown that are located elsewhere (e.g., in circuitry receiving the output of the amplifier 100). The current source 150 is connected between Vdd and the voltage biasing circuit 160. The voltage biasing circuit 160 utilizes the current source 150 and Vdd to bias the voltage provided to the first and second transistors 110, 120. The resistor 170 is coupled between the voltage biasing circuit 160 and the gate of the first transistor 110. The resistor 170 has a large value so that the bias voltage provided thereto has low noise. In some cases resistor 170 may be replaced with an inductor.

The inductor 180 is coupled between the voltage biasing circuit 160 and the gate of the second transistor 120. The inductor 180 increases the gate inductance, lowers the input impedance (looking into source), and increases the output impedance of the second transistor 120. This in turn reduces Miller feedback from gate to drain capacitance (Cgd) of the first transistor 110. These changes enhance the gain of the amplifier 100 from what it may have been without the inductor 180. The enhanced gain may be achieved without increasing (or substantially increasing) the noise figure of the amplifier 100. The improvement in gain without an increase in noise figure results in an increase in the sensitivity of the amplifier 100.

The inductor 180 may provide some beneficial tuning of the second transistor 120. The inclusion of the inductor 180 may also shift the tuning of the amplifier 100. However, the shift in tuning of the amplifier 100 may be easily accommodated by re-tuning the input and output matching networks 130, 140.

The amount of gain that is desired and achieved depends on the application and technology employed to implement the amplifier 100. A desired gain increase may be on the order of 3-6 db. A larger increase in gain may cause instability. The desired gain may be achieved with a relatively modest value (e.g., 100-500 pico-Henries) for the inductor 180. The inductor value is large enough to control, but small enough not to require significant die area.

The voltage biasing circuit 160 may be located apart from the second transistor 120 so that the inductor 180 can be formed in interconnect metal so that no additional die area is required to implement.

The use of the inductor 180 can be implemented to enhance the gain of a high-frequency amplifier. A high-frequency low noise amplifier may be one practical application of the use of the inductor 180. The use of the inductor 180 may increase the gain in amplifiers and systems with marginal capability/performance for a given power consumption. In a scaled digital CMOS process where the transistors have severe short channel effects (low output resistance) and/or low Q inductors (or with resistive loads), this technique can be employed to increase gain which would otherwise be low. The increased gain is important for making high-performance radios, such as those fabricated in CMOS, particularly scaled CMOS, and digital CMOS.

Gain boosting generated by the inductor 180 may also be used to obtain adequate performance at lower current to save power for battery operated devices. This may enable low power operation of a receiver in a radio by reducing the noise contribution of later components in the receiver chain. A low power receiver is important for a variety of radio standards, particular if they operate from a battery.

FIG. 1B illustrates a simplified detailed schematic of the example amplifier 100. The input matching network 130 may include a series inductor 132 coupled to the gate of the first transistor 110. The inductor 132 may be coupled in series to a capacitor 134. The input matching network 130 may include other components that are not illustrated for ease of understanding. The input matching network 130 is in no way intended to be limited to the inductor 132 and capacitor 134 in series. Rather, the input matching network 130 can be any type of RF circuitry (e.g., spiral inductors) utilized for matching of the input that does not interfere with the voltage bias being applied to the gate of the first transistor 110.

The output matching network 140 may include an inductor 142. It may also include other components that are not illustrated for ease of understanding. The output matching network 140 is in no way intended to be limited to the inductor 142. Rather, the output matching network 140 can be any type of RF circuitry utilized for matching of the output.

The voltage biasing circuit 160 may include two transistors 162, 164 connected in series. The gates of each of the transistors 162, 164 may be connected to the drain of the transistors 162, 164 to provide a DC voltage for biasing. The voltage biasing circuit 160 is in no way intended to be limited to transistors 162, 164. Rather, the voltage biasing circuit 160 can be a battery, capacitor or any type of analog and/or RF circuitry that provides biasing and a low impedance to the gates of the transistors 110, 120.

FIGS. 1A and 1B illustrated the tuned cascode amplifier 100 as two transistors 110, 120 in series, however the amplifier 100 is in no way intended to be limited thereto. Rather, various other embodiments are within the current scope. For example, the common gate transistor 120 could be two transistors in series. The bias provided to the gate of the two transistors could be the same, could be different but be supplied from the same voltage biasing circuit 160, or the bias provided to one of the transistors could be provided from an alternative bias source (not illustrated). The amplifier 100 may include auxiliary circuitry (e.g., one or more transistors) for improved linearity where the auxiliary circuitry is on an auxiliary path (e.g., in parallel to the transistors 110, 120). Neither, the auxiliary circuitry nor the auxiliary path are illustrated.

Although the disclosure has been illustrated by reference to specific embodiments, it will be apparent that the disclosure is not limited thereto as various changes and modifications may be made thereto without departing from the scope. Reference to “one embodiment” or “an embodiment” means that a particular feature, structure or characteristic described therein is included in at least one embodiment. Thus, the appearances of the phrase “in one embodiment” or “in an embodiment” appearing in various places throughout the specification are not necessarily all referring to the same embodiment.

The various embodiments are intended to be protected broadly within the spirit and scope of the appended claims.

What is claimed:

1. An amplifier comprising
a first transistor coupled to ground;
a second transistor coupled to the first transistor and a supply voltage;
a voltage biasing circuit to provide biased voltages to the first and second transistors; and
an inductor coupled between the voltage biasing circuit and the second transistor.

2. The amplifier of claim 1, further comprising an input matching network coupled to the first transistor.

3. The amplifier of claim 1, further comprising an output matching network coupled to the second transistor.

4. The amplifier of claim 1, further comprising a current source coupled between the supply voltage and the voltage biasing circuit.

5. The amplifier of claim 4, wherein the voltage biasing circuit biases the voltages based on the current source and supply voltage.

6. The amplifier of claim 1, further comprising a resistor coupled between the voltage biasing circuit and the first transistor.

7. The amplifier of claim 1, wherein the inductor is coupled to the gate of the second transistor.

8. The amplifier of claim 1, wherein the inductor has a value in the range of approximately 100 to 500 pico-Henries.

9. The amplifier of claim 1, wherein the inductor is formed in interconnect metal.

10. The amplifier of claim 1, utilized in combination with a battery to power the amplifier.

11. The amplifier of claim 1, implemented in a low power receiver.

12. An amplifier comprising
a pair of transistors coupled together in series;
a voltage biasing circuit to provide biased voltages to the pair of transistors;
an input matching network coupled to a first transistor of the pair of transistors;
an output matching network coupled to a second transistor of the pair of transistors; and
an inductor coupled between the voltage biasing circuit and the second transistor.

13. The amplifier of claim 12, wherein the inductor is coupled to the gate of the second transistor.

14. The amplifier of claim 12, utilized in combination with an antenna to receive signals to be amplified.

15. The amplifier of claim 12, implemented in a high-performance radio.
